(19) United States
(12) Patent Application Publication
(10) Pub. No.: US 2025/0380419 A1
(43) Pub. Date: Dec. 11, 2025

(54) LATERAL WORD LINE CONTACTS FOR MEMORY DEVICES

(71) Applicant: Micron Technology, Inc., Boise, ID (US)

(72) Inventors: Yoshiaki Fukuzumi, Yokohama (JP); David H. Wells, Boise, ID (US); Harsh Narendrakumar Jain, Boise, ID (US)

(21) Appl. No.: 19/215,468

(22) Filed: May 22, 2025

Related U.S. Application Data
(60) Provisional application No. 63/657,090, filed on Jun. 6, 2024.

(51) Int. Cl. H10B 43/27; H10B 43/10

(52) U.S. Cl. CPC H10B 43/27; H10B 43/10

(57) ABSTRACT

Methods, systems, and devices for lateral word line contacts for memory devices are described. A memory architecture may include a stack of materials including layers of word lines. The memory architecture may include array regions including memory cells coupled with the word lines. The memory architecture may include contact regions including word line contact pillars extending through the stack of materials, each coupled with a respective word line at a respective target layer of the stack of materials. The contact regions may include subsets of guard pillars extending through the stack of materials, each subset associated with isolating the respective word line contact pillar from word lines at other layers of the stack of materials different from the target layer. The memory architecture may include a staircase region and electrically isolating pillars at least partially surrounding the staircase region.

### CROSS REFERENCE

The present Application for Patent claims priority to U.S. Patent Application No. 63/657,090 by Fukuzumi et al., entitled “LATERAL WORD LINE CONTACTS FOR MEMORY DEVICES,” filed Jun. 6, 2024, which is assigned to the assignee hereof, and which is expressly incorporated by reference in its entirety herein.

### TECHNICAL FIELD

The following relates to one or more systems for memory, including lateral word line contacts for memory devices.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports lateral word line contacts for memory devices in accordance with examples as disclosed herein.

FIG. 2A, 2B, 2C, 2D, 2E, 2F, 2G, 2H, 2I, 2J, 2K, 2L, 2M, 2N, 2O, 2P, 2Q, 2R, 2S, and 2T show examples of processing steps that support lateral word line contacts for memory devices in accordance with examples as disclosed herein.

FIG. 3 shows an example of a memory architecture that supports lateral word line contacts for memory devices in accordance with examples as disclosed herein.

FIG. 4 shows a flowchart illustrating a method or methods that support lateral word line contacts for memory devices in accordance with examples as disclosed herein.

### DETAILED DESCRIPTION

In some memory systems, one or more memory devices, such as NAND devices (e.g., NAND dies), may be scaled (e.g., decreased in size) to support implementing a relatively greater quantity of memory devices in the memory system, or to support a relatively smaller memory system overall (e.g., implementing a same quantity of memory devices in the memory system). In some such memory systems, scaling the one or more memory devices may include scaling a memory architecture of one or more memory arrays implemented by the one or more memory devices. However, scaling the memory architecture may include reducing an area associated with access lines of the memory architecture. For example, scaling the memory architecture may include scaling word line contacts associated with coupling word lines at specific layers of the memory architectures with word line contact pillars. In some cases, scaling the word line contacts may cause challenges associated with manufacturing the scaled memory architecture. That is, processes (e.g., manufacturing operations) to support scaling the memory architecture may be relatively expensive and/or complex to implement. For example, implementing different processes for forming each pillar etch for different types of pillars (e.g., word line contact pillars, guard pillars, cell pillars, electrically isolating pillars) of the memory architecture may be relatively expensive and complex, among other challenges.

In accordance with examples as described herein, a memory architecture may be manufactured using similar processes for various elements of the memory architecture. For example, a same pillar etch may be used to form multiple holes through a stack of memory materials. The holes may subsequently be used to form different types of pillars of the memory architecture, which may be relatively inexpensive and simple to implement. The memory architecture may include word line contact pillars for coupling with (e.g., for connection with, for access to) word lines at specific layers of the memory architecture. The memory architecture may also include guard pillars associated with each word line contact pillar, cell pillars associated with forming memory cells of the memory architecture, and/or electrically isolating pillars associated with a staircase region of the memory architecture. In some such examples, the pillars may be etched in a single process and filled with one or more sacrificial materials, and then each different type of pillar may be selectively formed by removing the sacrificial material from sets of pillars at different times and depositing material in the empty pillars after removing the sacrificial material accordingly. In some implementations, lateral word line contacts of the memory architecture may be formed such that the sacrificial material at a target layer of the memory architecture may be etched to couple the word line at the target layer with a respective word line contact pillar. Implementing the processes described herein may support scaling the memory architecture with relatively inexpensive and simple manufacturing operations, among other advantages. For example, the word line contacts may be formed within the holes etched at the same time as the holes for memory cells and other memory architectures, which may reduce complexity and processing for formation of the memory device, while maintaining reliability and continuity between connections within the memory device.

In addition to applicability in memory systems described herein, techniques for lateral word line contacts for memory devices may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may support the security of electronic devices and systems by improving connectivity using lateral word line contacts in a memory architecture, which may improve reliability associated with operating a memory device implementing the memory architecture, among other benefits.

In addition to applicability in memory systems as described herein, techniques for lateral word line contacts for memory devices may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by consolidating manufacturing processes associated with forming a memory architecture with lateral word line contacts, which may reduce electronic waste otherwise associated with performing many manufacturing processes (e.g., as in previous implementations), among other benefits.

Features of the disclosure are illustrated and described in the context of systems, devices, and circuits. Features of the disclosure are further illustrated and described in the context of processing steps, memory architectures, and flowcharts.

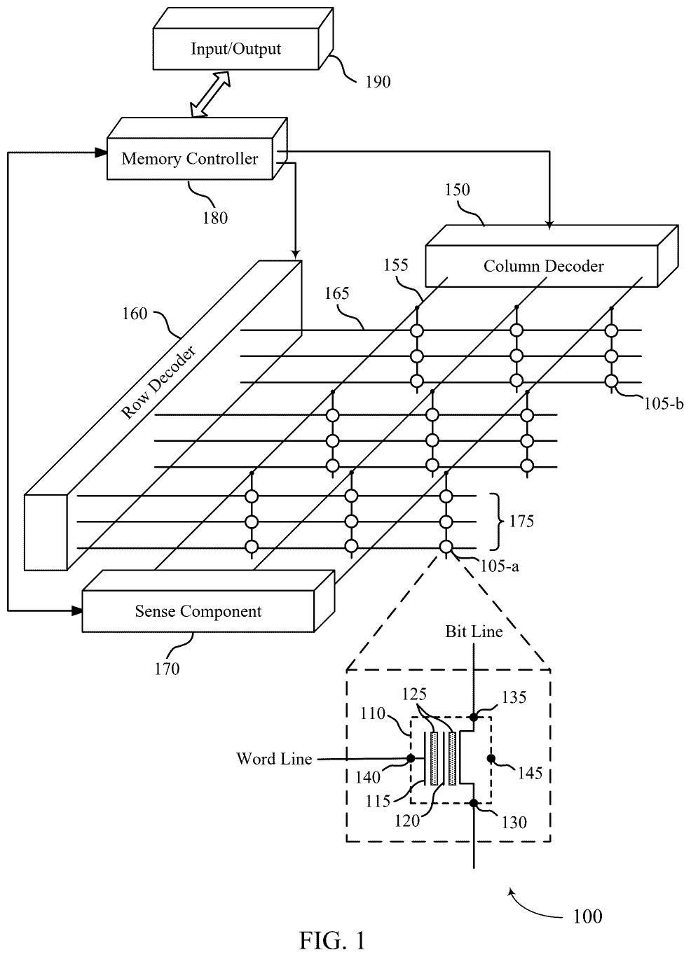

FIG. 1 shows an example of a memory device 100 that supports lateral word line contacts for memory devices in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, charge-trap material, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105. For example, the sense component 170 may determine the logic value of a TLC memory cell 105 based on the current or potential of the bit line 155 by applying seven or eight different read voltages to the control gate to define eight threshold voltage values.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. In some cases, when a second voltage is applied to the bit line 155, the potential difference between the control node 140 and the bulk node 145 (e.g., which is the channel of the transistor 110) may cause electron injection to be inhibited due to reduced electric field across cell film of the transistor 110 (e.g., by raising the potential of the bulk node 145 via controlling the potential of bit line 155, depending on the data to be written). Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as select lines or access lines.

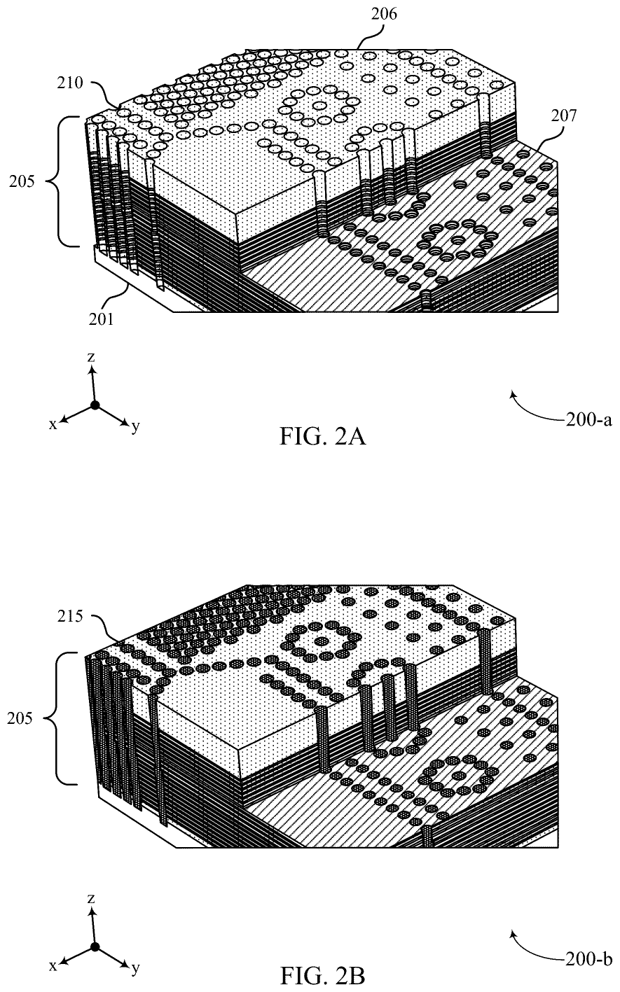

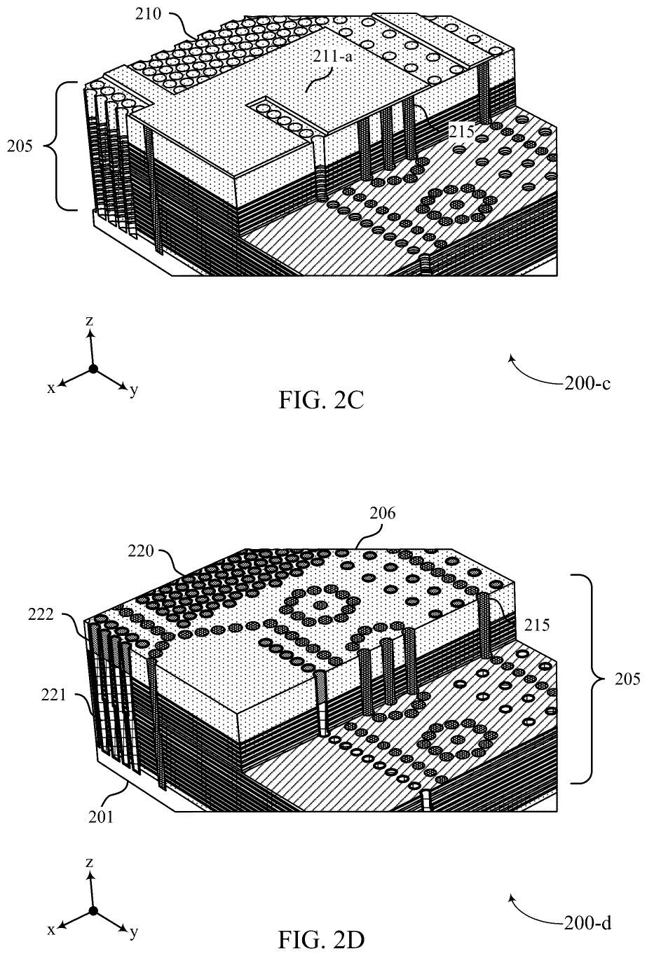

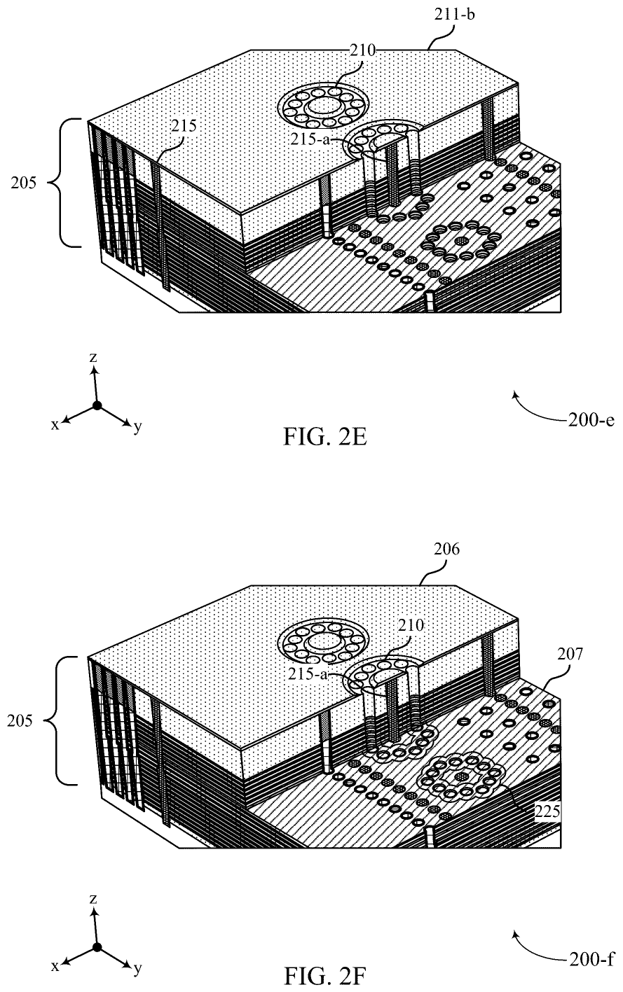

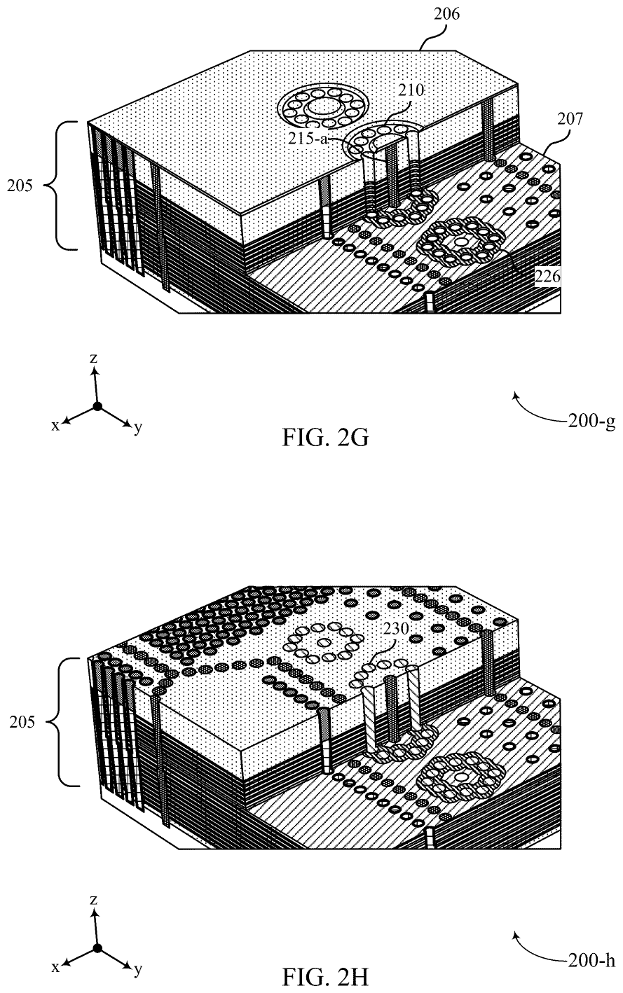

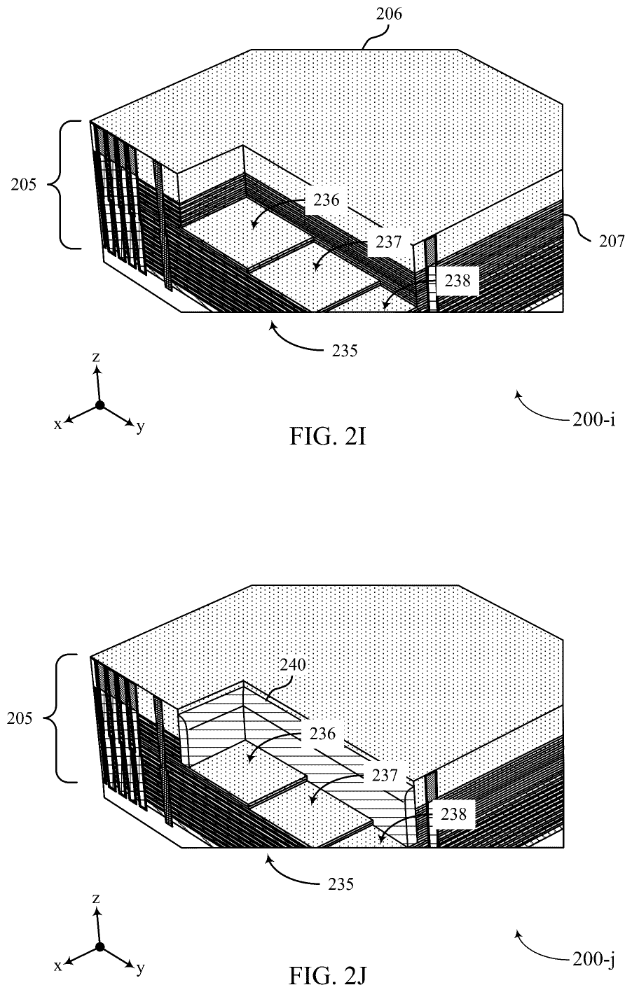

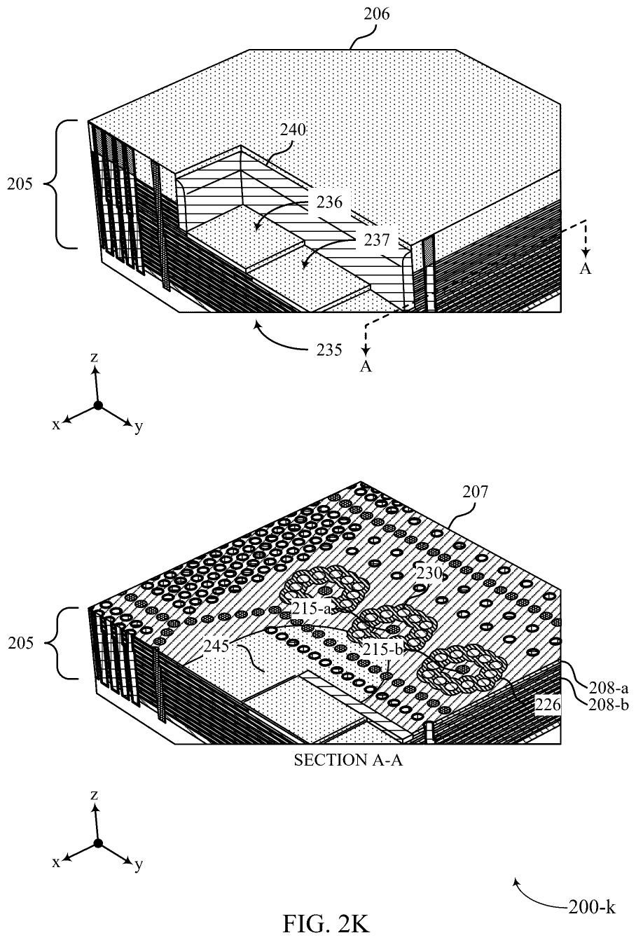

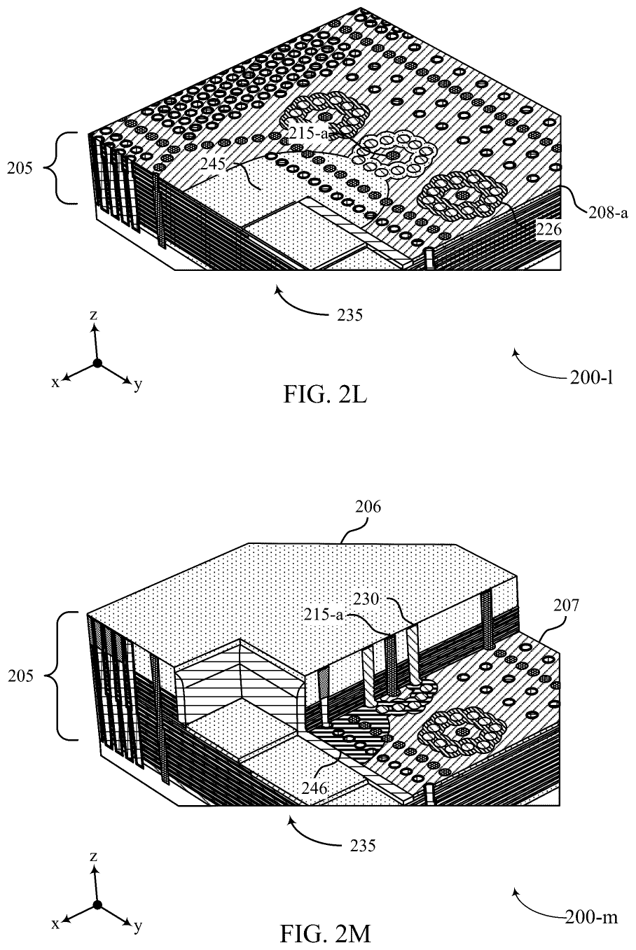

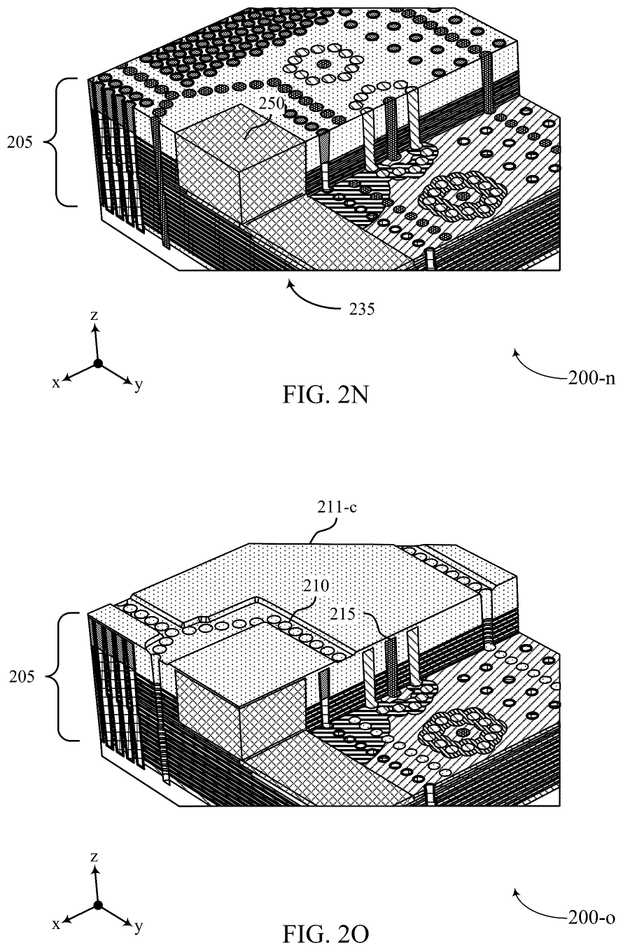

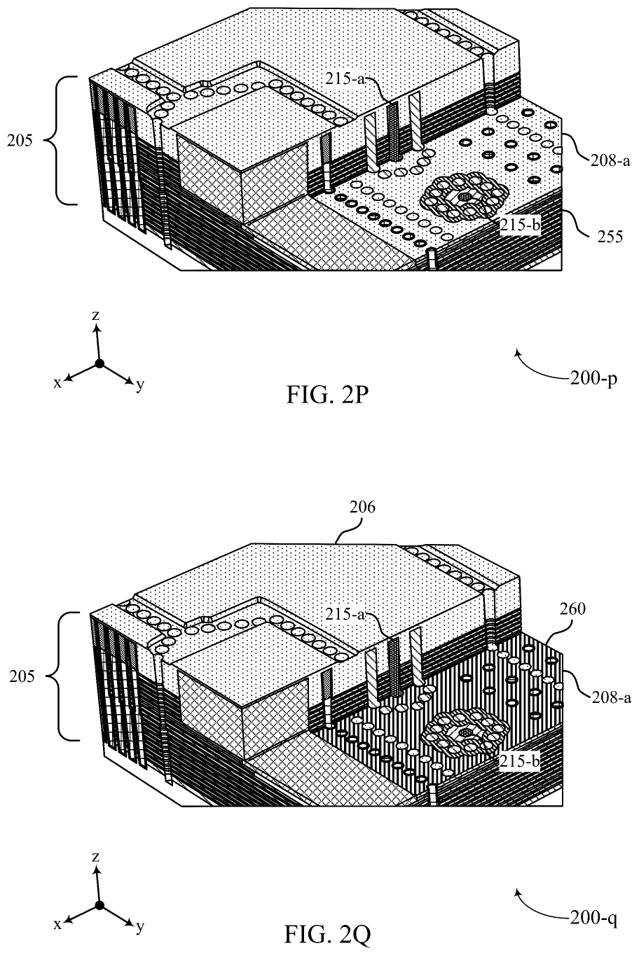

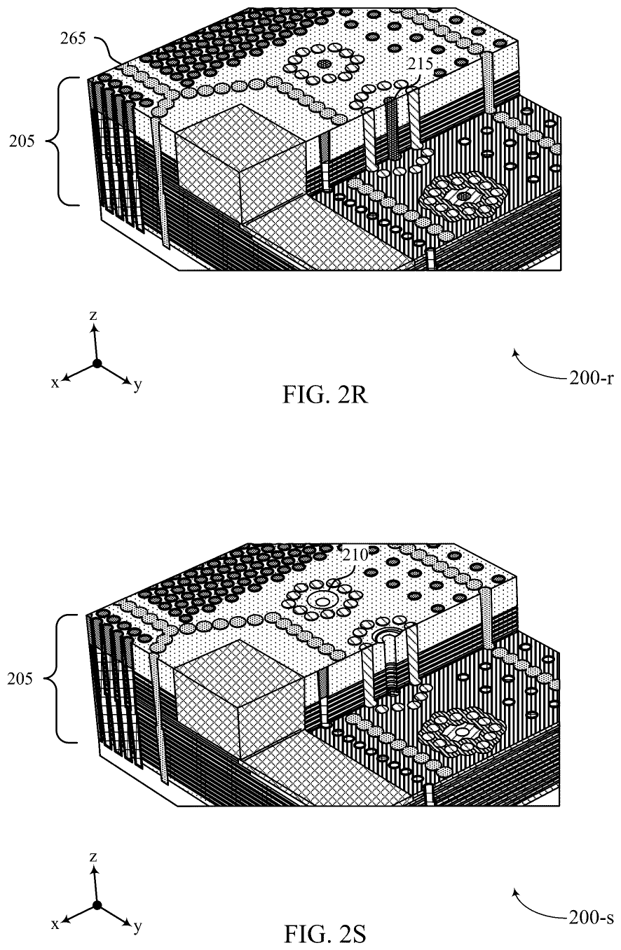

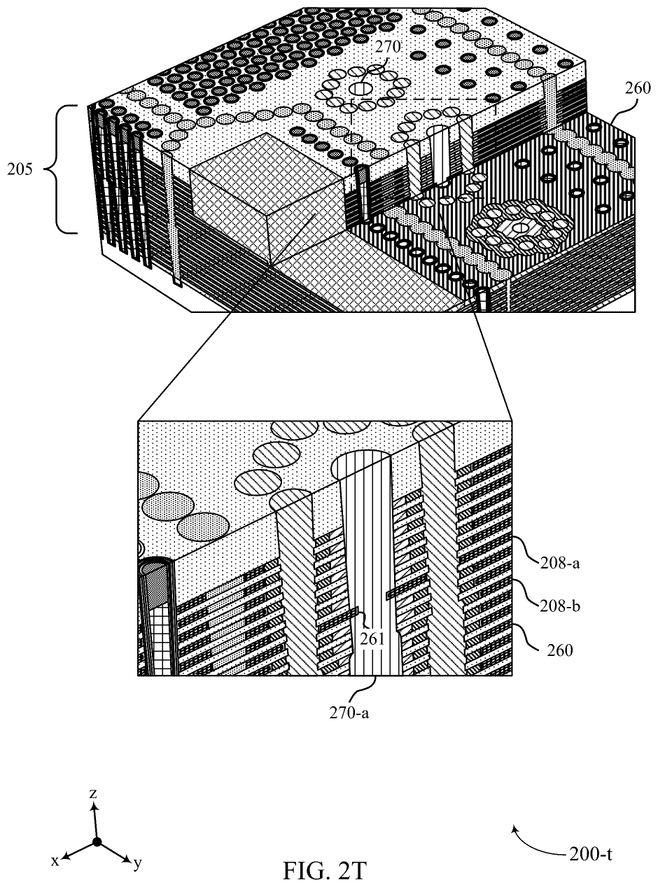

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 (e.g., with transistors connected in series) may be referred to as a string of memory cells 105 (e.g., as described with reference to one or more of FIG. 2A thru 2T).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In accordance with examples as described herein, a memory architecture of the memory device 100 may be manufactured using similar processes for various elements of the memory architecture. For example, a same pillar etch may be used to form different types of pillars of the memory architecture, which may be relatively inexpensive and simple to implement. The memory architecture may include word line contact pillars for coupling with the word lines 165 at specific layers of the memory architecture. The memory architecture may also include guard pillars associated with each word line contact pillar, cell pillars associated with forming the memory cells 105, and electrically isolating pillars associated with a staircase region of the memory architecture. In some such examples, the pillars may be etched and filled with sacrificial material, then each different type of pillar may be selectively formed in the sacrificial material (e.g., formed by using or removing the sacrificial material one by one). In some implementations, lateral word line contacts of the memory architecture may be formed such that sacrificial material at a target layer of the memory architecture may be etched to couple the word line 165 at the target layer with a respective word line contact pillar. Implementing the processes described herein may support scaling the memory architecture with relatively inexpensive and simple manufacturing operations.

FIGS. 2A through 2T show examples of processing steps 200 that support lateral word line contacts for memory devices in accordance with examples as disclosed herein. FIGS. 2A through 2T show various diagonal views (e.g., trimetric views) of a memory architecture, which may be an example of a memory architecture implemented by a memory device 100, as described with reference to FIG. 1. The processing steps 200 may illustrate operations associated with forming lateral word line contacts in the memory architecture. Performing the processing steps 200 may consolidate processing steps otherwise associated with forming a memory architecture. For example, the processing steps 200 may support relatively inexpensive and simple operations associated with forming lateral word line contacts, among other advantages.

For illustrative purposes, aspects of the memory architecture may be described with reference to an x-direction, a y-direction, and a z-direction of the illustrated coordinate systems. For example, processing steps 200-a, 200-b, 200-c, 200-d, 200-c, 200-f, 200-g, 200-h, 200-i, 200-j, 200-k, 200-l, 200-m, 200-n, 200-o, 200-p, 200-q, 200-r, 200-s, 200-t illustrate the memory architecture from trimetric views where a substrate 201 of the memory architecture may be associated with an xy-plane, where the memory architecture extends a distance along the z-direction. Additionally, processing steps 200 may illustrate the memory architecture with a partial cross-sectional view, such that a portion of the memory architecture may be removed from the trimetric view to illustrate a cross-section of the memory architecture. Although the processing steps 200 illustrate examples of relative dimensions and quantities of various features, aspects of the memory architecture may be implemented with other relative dimensions or quantities of such features in accordance with examples as disclosed herein. In the following description of the processing steps 200, some methods, techniques, processes, and operations may be performed in different orders or at different times. Further, some operations may be left out of the processing steps 200, or other operations may be added to the processing steps 200.

Operations illustrated in and described with reference to FIGS. 2A through 2T may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 2A illustrates a processing step 200-a associated with forming a stack of materials 205. For example, forming the stack of materials 205 may include depositing alternating layers of a dielectric material 206 and a sacrificial material 207 above the substrate 201 (e.g., an xy-plane upon which materials may be formed), where the substrate 201 may be associated with complementary metal-oxide semiconductor (CMOS) circuitry. In some such examples, depositing the alternating layers may include depositing a layer of the dielectric material 206, then depositing a layer of the sacrificial material 207 above the layer of the dielectric material 206. Accordingly, the dielectric material 206 and the sacrificial material 207 may be similarly deposited to form alternating layers, where the height of the stack of materials 205 may be based on the quantity and height of each of the alternating layers. In some implementations, the dielectric material 206 may be an oxide material (e.g., or similar dielectric material), such as silicon oxide, silicon oxycarbide, silicon oxynitride, or silicon nitride. In some implementations, the sacrificial material 207 may be a variation of nitride.

After forming the stack of materials 205, cavities 210 (e.g., holes) may be formed in the stack of materials 205. For example, the cavities 210 may extend along the z-direction to the substrate 201, and may be arranged in a pattern relative to an xy-plane. Forming the cavities 210 may include removing portions of the stack of materials 205 in accordance with the pattern. In some cases, removing the portions of the stack of materials 205 may include performing a high aspect ratio contact etch procedure. For example, a mask (e.g., a photolithographic mask) may be formed above the stack of materials 205, where the mask may selectively cover the stack of materials 205 such that the mask may expose the portions of the stack of materials 205 associated with the cavities 210. In some such examples, the stack of materials 205 may be etched based on the mask, such that the portions of the stack of materials 205 exposed by the mask may be removed. In some cases, each cavity 210 may be associated with forming a pillar, such that the pattern of the cavities 210 may include multiple arrangements associated with different types of pillars. For example, each cavity 210 may be associated with forming a cell pillar, a guard pillar, a word line contact pillar, or an electrically isolating pillar of the memory architecture.

FIG. 2B illustrates a processing step 200-b associated with forming sacrificial pillars 215 in the stack of materials 205. For example, the sacrificial pillars 215 may be formed by depositing one or more sacrificial materials within the cavities 210. In some cases, forming the sacrificial pillars 215 may include depositing a sacrificial liner within the cavities 210, then depositing a sacrificial filler material within the cavities 210. In some such cases, the sacrificial liner may be deposited and etched to a desired thickness prior to depositing the sacrificial filler material within the cavities 210. In some examples, the sacrificial liner may be an oxide-based liner material, and the sacrificial filler material may be an oxide-based material, such as silicon oxide, silicon oxycarbide, silicon oxynitride, silicon nitride, or carbon material. In some implementations, a portion of the sacrificial filler material on top of the stack of materials 205 may be removed (e.g., using chemical-mechanical polishing (CMP) or dry-etching).

FIG. 2C illustrates a processing step 200-c associated with removing a first set of the sacrificial pillars 215 from the stack of materials 205. For example, the one or more sacrificial materials in a set of the sacrificial pillars 215 may be removed to re-form the cavities 210 in the stack of materials 205 at the first set of sacrificial pillars 215. In some cases, the set of sacrificial pillars 215 may be removed using a mask dielectric layer 211-a (e.g., a silicon oxide film) in accordance with a pattern. For example, the mask dielectric layer 211-a may be formed above the stack of materials 205, where the mask dielectric layer 211-a may selectively cover the stack of materials 205 such that the mask dielectric layer 211-a may cover a second set of sacrificial pillars 215 and may expose other pillars, including the first set of sacrificial pillars. In some such examples, the one or more sacrificial materials associated with the first set of sacrificial pillars 215 may be selectively etched based on the mask dielectric layer 211-a, such that the one or more sacrificial materials exposed by the mask dielectric layer 211-a may be removed. In some cases, selectively etching the first set of sacrificial pillars 215 may be based on using an etchant associated with removing the one or more sacrificial materials. The stack of materials 205 may thereby include multiple cavities 210 and one or more sacrificial pillars 215 that are still filled in with the sacrificial material (e.g., the sacrificial pillars 215 distributed in hexagonal formations in FIG. 2C).

FIG. 2D illustrates a processing step 200-d associated with forming cell pillars 220 in the stack of materials 205. For example, the cell pillars 220 may be formed by depositing memory material 221 into the cavities 210 formed at processing step 200-c. The memory material 221 may be formed by conformal deposition, transistor channel semiconductor material, and dielectric filler material deposited a distance along the z-direction (e.g., up to a top layer of the dielectric material 206) within the cavities 210. In some implementations, the memory material 221 may be deposited in alternating layers with a dielectric material. In some such implementations, the memory material 221 at each layer may be associated with forming one or more memory cells at the respective layer of the stack of materials 205. After depositing the memory material 221 within the cavities 210, a polysilicon plug 222 may be deposited within the cavities 210. For example, the polysilicon plug 222 may be deposited up to a top surface of the stack of materials 205 within each of the cavities 210. In some such examples, the polysilicon plug 222 may be formed in the top portion of the cavities 210 from a surface of the stack of materials 205 to a depth near a top-most layer of the sacrificial material 207.

FIG. 2E illustrates a processing step 200-e associated with removing another set of the sacrificial pillars 215 from the stack of materials 205. For example, the one or more sacrificial materials in a second set of the sacrificial pillars 215 may be removed to re-form the cavities 210 in the stack of materials 205 where the second set of sacrificial pillars 215 were located before the processing step 200-c. In some cases, the sacrificial material may be removed from the second set of sacrificial pillars 215 using a mask dielectric layer 211-b in accordance with a pattern. For example, the mask dielectric layer 211-b may be formed above the stack of materials 205, where the mask dielectric layer 211-b may selectively cover the stack of materials 205 such that the mask dielectric layer 211-b may expose the second set of sacrificial pillars 215. The second set of sacrificial pillars 215 may correspond to the pillars that are distributed in hexagonal shapes positioned adjacent to one another in the stack of materials 205. In some such examples, the one or more sacrificial materials associated with the second set of sacrificial pillars 215 may be selectively etched based on the mask dielectric layer 211-b, such that the one or more sacrificial materials exposed by the mask dielectric layer 211-b may be removed and the cavities 210 may be formed. In some cases, selectively etching the set of sacrificial pillars 215 may be based on using an etchant associated with removing the one or more sacrificial materials. In some examples, the set of sacrificial pillars 215 may include subsets of sacrificial pillars 215 each at least partially surrounding a sacrificial pillar 215-a. In some examples, the mask dielectric layer 211-b may cover a respective sacrificial pillar 215-a in the center of each subset of sacrificial pillars, such that the sacrificial material remains in the central sacrificial pillar 215-a in each subset and is at least partially surrounded by one or more cavities 210 (e.g., in the central region of a hexagonal structure of cavities 210).

FIG. 2F illustrates a processing step 200-f associated with removing portions of the sacrificial material 207 within the stack of materials 205. For example, the cavities 210 may be used to remove the portions of the sacrificial material 207, which may form recesses 225 in the layers of the sacrificial material 207. For example, the recesses 225 may extend between the layers of dielectric material 206 along the z-direction, and may extend adjacent to the cavities 210 some distance in the respective layer of the sacrificial material 207 (e.g., in the respective xy-plane). In some cases, forming the recesses 225 may not remove portions of the sacrificial material 207 surrounding the sacrificial pillars 215-a. For example, portions of the sacrificial material 207 may remain adjacent to the sacrificial pillars 215-a. The processing step 200-f may merge each subset of cavities 210 to form a ring-link structure, such as the recess 225, that at least partially surrounds the sacrificial pillars 215-a. For example, at each layer of the sacrificial material, there may be a ring-shaped recess 225 (e.g., absence of material) that surrounds respective sacrificial pillars 215-a at the respective layer. The recess 225 may connect each of the cavities 210 in a circular or otherwise closed loop. The cavities 210 may be separated by dielectric material at each dielectric material layer between the layers of sacrificial material 207.

FIG. 2G illustrates a processing step 200-g associated with forming a polysilicon material 226 at the recesses 225. For example, the polysilicon material 226 may be deposited within the recesses 225, such that the polysilicon material 226 may extend between the layers of dielectric material 206 along the z-direction, and may extend adjacent to the cavities 210 in the respective layer of the sacrificial material 207. In some such examples, the polysilicon material 226 may extend adjacent to the cavities 210 in the respective layer of the sacrificial material 207, and may be recessed such that the polysilicon material 226 may be separated between different layers. In some examples, the cavities 210 may be used to deposit the polysilicon material 226 within the recesses 225 at every other layer (e.g., between the layers of dielectric material 206). In some implementations, the polysilicon material 226 may be an example of a guard poly material, such that the polysilicon material 226 may be selective against metallization operations (e.g., may not be removed during replacing sacrificial material with conductive material. The polysilicon material 226 may form a loop that at least partially surrounds the central sacrificial pillar 215-a in each subset of cavities 210 and at least partially surrounds a portion of sacrificial material 207 that is within the loop of polysilicon material 226. The polysilicon material 226 may function as a replacement stopper after formation. That is, the material of the replacement stopper may be polysilicon, doped polysilicon, a dielectric material different from silicon oxide or silicon nitride (e.g., a high dielectric constant material, such as hafnia), or thin thermal oxidation of the sacrificial material 207 (e.g., converted silicon oxide from silicon nitride).

FIG. 2H illustrates a processing step 200-h associated with forming guard pillars 230 in the stack of materials 205. For example, the guard pillars 230 may be formed by depositing a guard material into the cavities 210 associated with the second set of sacrificial pillars 215 removed at processing step 200-c. In some implementations, the guard material may be a dielectric material, such as silicon oxide.

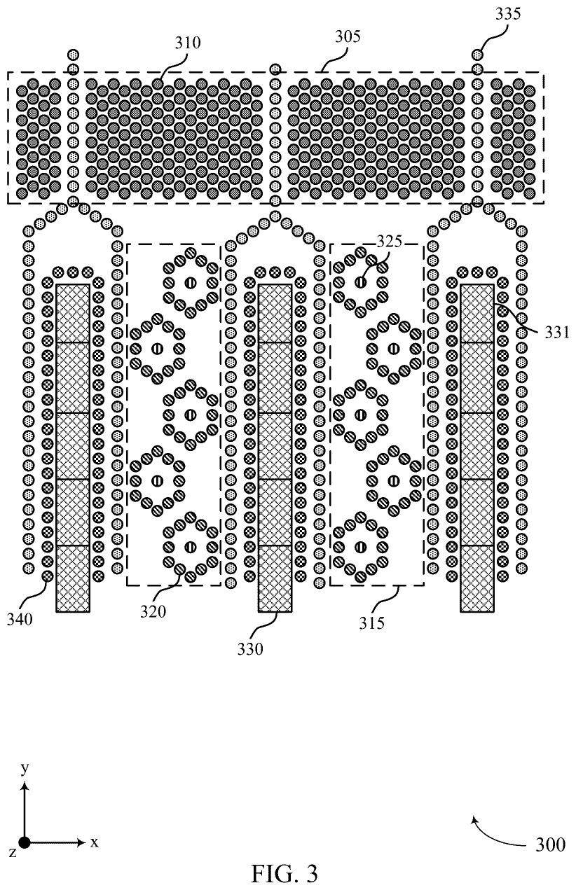

FIG. 2I illustrates a processing step 200-i associated with forming a staircase region 235 in the stack of materials 205. For example, forming the staircase region 235 may include removing portions of the layers of the dielectric material 206 and the sacrificial material 207. In some cases, the staircase region 235 may be formed based on etching down (e.g., along the z-direction) to a quantity of layers using different etch depths along the y-direction. The layers of dielectric material 206 and sacrificial material 207 may be etched down to form multiple cascading tiers, such as the tiers 236, 237, and 238 illustrated in FIG. 2I. In some cases, the staircase region 235 may include a tier 236 etched to a first distance along the z-direction, a tier 237 etched to a second distance along the z-direction, and a tier 238 etched to a third distance along the z-direction. Each tier 236, 237, and 238 may be etched to a respective layer of the dielectric material 206. The staircase region 235 may be formed adjacent to the sacrificial pillars 215 and the cell pillars 220 within the xy-plane. For example, the sacrificial pillars 215 may surround the staircase region 235, and a row of cell pillars 220 may be adjacent to the staircase region 235 and the sacrificial pillars 215. In some examples, each tier within the staircase region 235 may be associated with a respective subset of guard pillars 230 of the multiple subsets of guard pillars 230. That is, each tier may be used to access a respective set of guard pillars 230 and corresponding central sacrificial pillar 215-a at a respective layer associated with the tier. Techniques for forming the tiers relative to the subsets of guard pillars 230 may provide for various different connection options, as described in further detail elsewhere herein, including with reference to FIG. 3. Although three tiers are illustrated herein, it is to be understood that a staircase region 235 may include any quantity of tiers, layers, and corresponding subsets of guard pillars 230.

FIG. 2J illustrates a processing step 200-j associated with forming a barrier 240 in the staircase region 235. For example, a barrier 240 may be deposited against sidewalls of the staircase region 235. In some cases, the barrier 240 may extend to a depth of each tier 236, 237, and 238 along the z-direction, and the barrier 240 may extend along the x-direction and y-direction for each sidewall of the staircase region 235. In some examples, forming the barrier 240 in the staircase region 235 may include depositing the barrier material and etching the barrier 240 to a desired thickness along the x-direction and the y-direction (e.g., for each respective sidewall of the staircase region 235) based on depositing the barrier 240. For example, forming the barrier 240 may include etching the barrier 240 by anisotropic etching (e.g., reactive ion etching) sidewalls of the barrier 240 remain around the staircase region 235. The barrier 240 may be removed by operations targeting between the tiers of the staircase region 235 by over-etching the anisotropic etching of the barrier 240. In some examples, the barrier 240 may include a polysilicon material. In some examples, the barrier 240 may include a replacement stopper material.

FIG. 2K illustrates a processing step 200-k associated with removing a portion of the sacrificial material 207 at a target layer 208-a of the stack of materials 205. For example, FIG. 2K illustrates the memory architecture after performing the processing step 200-k from a trimetric view, and a cross-section A-A from a trimetric view of the target layer 208-a. The processing step 200-k may include removing a portion of a layer of the sacrificial material 207, where the layer is a target layer 208-a of the stack of materials 205. In some cases, the staircase region 235 may be used to remove the portion of the sacrificial material 207, based on etching the stack of materials 205 at the tier 236 of the staircase region 235. That is, the sacrificial material 207 at the target layer 208-a may be exposed by the tier 236 of staircase region 235, and the sacrificial material 207 may be etched based on the exposure. In some cases, the barrier 240 may not protect the stack of materials 205 at the target layer 208-a based on removing the portion of the sacrificial material 207.

In some cases, removing the portion of the sacrificial material 207 at the target layer 208-a may form a cavity 245 (e.g., an absence of material) at the target layer 208-a. The cavity 245 may extend between (e.g., along the z-direction) adjacent layers of the dielectric material 206 within the stack of materials 205. The cavity 245 may extend from the staircase region 235 (e.g., from an edge of a staircase in the staircase region 235) to the polysilicon material 226 surrounding the guard pillars 230 associated with the sacrificial pillar 215-a. In some cases, removing the portion of the sacrificial material 207 at the target layer 208-a may include removing another portion of the sacrificial material 207 at one or more other target layers, such as layer 208-b, of the sacrificial material 207. For example, the other portion of the sacrificial material 207 may be removed to form another cavity 245 at the layer 208-b extending to another set of guard pillars 230 (e.g., extending from another edge of the staircase region 235 to another set of guard pillars 230) associated with another sacrificial pillar 215-b. In some such examples, the barrier 240 may not protect the stack of materials 205 at the target layer 208-b based on removing the other portion of the sacrificial material 207.

The cavity 245 may extend some distance in each direction within the target layer 208-a. In some examples, a size of the cavity 245 may vary based on one or more etch parameters associated with the etch. The cavity 245 may at least extend to a portion of the polysilicon material 226 around the target set of guard pillars 230 in the target layer 208-a. That is, at least a portion of the polysilicon material 226 may be exposed via the cavity and the corresponding tier 236 of the staircase region 235.

FIG. 2L illustrates a processing step 200-1 associated with removing the polysilicon material 226 at the target layer 208-a. FIG. 2L illustrates another view of the cross-section A-A from a trimetric view of the target layer 208-a. For example, the polysilicon material 226 surrounding the guard pillars 230 associated with the sacrificial pillar 215-a may be removed from the target layer 208-a. The polysilicon material 226 may be removed via the cavity 245 and corresponding opening in the tier 236 as part of an exhume or etch process. In some cases, removing the polysilicon material 226 from the target layer 208-a at the sacrificial pillar 215-a may extend the cavity 245 at the target layer 208-a. Removing the polysilicon material 226 at the target layer 208-a may not remove the polysilicon material 226 at other layers of the stack of materials 205 associated with the sacrificial pillar 215-a because the cavity 245 may be specific to the target layer 208-a based on the tier 236 being associated with the target layer 208-a.

FIG. 2M illustrates a processing step 200-m associated with depositing a sacrificial material 246 within the cavity 245. For example, the sacrificial material 246 may be deposited within the cavity 245 using the staircase region 235 (e.g., via the tier 236). The sacrificial material 246 may extend between (e.g., along the z-direction) adjacent layers of the dielectric material 206 within the stack of materials 205. The sacrificial material 246 may extend from the staircase region 235 to the guard pillars 230 associated with the sacrificial pillar 215-a. In some cases, the sacrificial material 246 may be a similar material as the sacrificial material 207, such that the sacrificial material 246 may be a nitride-based material. The sacrificial material 246 may fill all or at least most of the empty space previously included in the cavity 245. In some implementations, the sacrificial material 246 may have an unfilled void within. As such, the sacrificial material 246 may fully or partially surround each of the guard pillars 230 in the target layer 208-a in a ring or loop-shape. Because the staircase region 235 is to be electrically isolated from the active block, the cavities 210 may be at least partially unfilled (e.g., may include one or more unfilled voids) to allow for cost reduction (e.g., low cost deposition process) and to provide mechanical stress relaxation of the memory architecture.

FIG. 2N illustrates a processing step 200-n associated with removing the barrier 240 from the staircase region 235. In some cases, removing the barrier 240 may include selectively etching the barrier 240 from the sidewalls of the staircase region 235. After removing the barrier 240 from the staircase region 235, the staircase region may be filled. For example, a structural material 250 may be deposited within the staircase region 235. The structural material 250 may be deposited and/or etched such that the structural material 250 may extend to a top surface of the stack of materials 205 along the z-direction, and may extend along the sidewalls of the staircase region 235. In some examples, the structural material 250 may be a tetraethoxysilane (TEOS) material, or some other material.

FIG. 2O illustrates a processing step 200-o associated with removing a third set of the sacrificial pillars 215 from the stack of materials 205. For example, the one or more sacrificial materials in the third set of the sacrificial pillars 215 may be removed to re-form the cavities 210 in the stack of materials 205 at the third set of sacrificial pillars 215. In some cases, the third set of sacrificial pillars 215 may be removed using a mask dielectric layer 211-c in accordance with a pattern. For example, the mask dielectric layer 211-c may be formed above the stack of materials 205, where the mask dielectric layer 211-c may selectively cover the stack of materials 205 such that the mask dielectric layer 211-c may expose the third set of sacrificial pillars 215 and may cover other pillars in the stack. In some such examples, the one or more sacrificial materials associated with the third set of sacrificial pillars 215 may be selectively etched based on the mask dielectric layer 211-c, such that the one or more sacrificial materials exposed by the mask dielectric layer 211-c may be removed. In some cases, selectively etching the set of sacrificial pillars 215 may be based on using an etchant associated with removing the one or more sacrificial materials.

FIG. 2P illustrates a processing step 200-p associated with removing the sacrificial material 207 from the stack of materials 205 (e.g., as part of a replacement gate procedure, for example). For example, the sacrificial material 207 may be removed from the layers of the stack of materials 205. In some cases, removing the sacrificial material 207 from the stack of materials 205 may include removing the sacrificial material 246 from the target layer 208-a of the stack of materials 205. The sacrificial material 207 and 246 may be removed from the sides of the stack of materials 205 and any sacrificial material 207 or 246 that is exposed may be removed as part of the etch. In some such cases, removing the sacrificial material 207 and the sacrificial material 246 from the target layer 208-a may not include removing the sacrificial material 207 that is surrounded by the one or more sets of guard pillars 230 and by the polysilicon material 226 at the target layer 208-a, at least because the polysilicon material 226 may block the inner region of sacrificial material 207 from exposure to the etch. However, removing the sacrificial material 207 and the sacrificial material 246 from the target layer 208-a may include removing the sacrificial material 207 that is adjacent to the guard pillars 230 and the sacrificial pillar 215-a of the target layer 208-a (e.g., without the polysilicon material 226 blocking the etch). In some cases, removing the sacrificial material 207 and the sacrificial material 246 from the stack of materials 205 may form cavities 255 between the layers of the dielectric material 206.

FIG. 2Q illustrates a processing step 200-q associated with forming conductive material 260 at the cavities 255. For example, the conductive material 260 may be deposited into the cavities 255 based on removing the sacrificial material 207 from the stack of materials 205. That is, the conductive material 260 may be deposited at the layers that previously included the sacrificial material 207, such that the conductive material 260 may alternate with layers of the dielectric material 206. Then, the conductive material 260 may be recessed to form linked cavity structures to be electrically isolated between the layers. Forming the conductive material 260 at the cavities 255 may include forming the conductive material 260 contacting the sacrificial pillar 215-a at the target layer 208-a of the stack of materials 205 at least because the guard pillars 230 may not fully surround the sacrificial pillar 215-a at the target layer 208-a. However, the conductive material 260 may not be in contact with the sacrificial pillar 215-b or any other sacrificial pillars at the target layer 208-a, and may not be in contact with the sacrificial pillar 215-a at any other layer. In some cases, the conductive material 260 around the sacrificial pillar 215-b may be recessed to form a linked cavity for electrical isolation. The conductive material 260 may be associated with word lines of the memory architecture, such that each layer of the conductive material 260 may be a word line of the memory architecture. Each word line of the memory architecture may be associated with accessing memory cells of the memory architecture (e.g., via the cell pillars 220). The contact between the conductive material 260 and the sacrificial pillar 215-a at the target layer 208-a may provide for subsequent contact between the word line and a word line contact and corresponding word line activation circuitry.

FIG. 2R illustrates a processing step 200-r associated with filling the linked cavities to form electrically isolating pillars 265 in the stack of materials 205. For example, the electrically isolating pillars 265 may be formed by depositing a dielectric material into the cavities 210 associated with the third set of sacrificial pillars 215 removed at processing step 200-o. In some examples, the electrically isolating pillars 265 may be merged, such that the dielectric material in each pillar is in contact with the dielectric material in one or more adjacent pillars, thereby forming a continuous line or curve of dielectric material between the sets of guard pillars 230 and the staircase region 235.

FIG. 2S illustrates a processing step 200-s associated with removing the remaining sacrificial pillars 215 from the stack of materials 205. For example, the one or more sacrificial materials in the remaining sacrificial pillars 215 may be removed to re-form the cavities 210 in the stack of materials 205 at the remaining sacrificial pillars 215. In some cases, the remaining sacrificial pillars 215 may be removed using a mask dielectric layer in accordance with a pattern. For example, the mask dielectric layer may be formed above the stack of materials 205, where the mask dielectric layer may selectively cover the stack of materials 205 such that the mask may expose the remaining sacrificial pillars 215. In some such examples, the one or more sacrificial materials associated with the remaining sacrificial pillars 215 may be selectively etched based on the mask dielectric layer, such that the one or more sacrificial materials exposed by the mask dielectric layer may be removed. In some cases, selectively etching the remaining sacrificial pillars 215 may be based on using an etchant associated with removing the one or more sacrificial materials.

The stack of materials 205 may thereby include, after the processing step 200-s, one or more sets of guard pillars 230 that each at least partially surround or are otherwise associated with a respective central cavity 210. Each set of guard pillars 230 may be surrounded by a polysilicon material 226 at one or more layers (e.g., layers of conductive material 260) and may not be surrounded by the polysilicon material 226 at a respective target layer 208-a.

FIG. 2T illustrates a processing step 200-t associated with forming word line contact pillars 270 in the stack of materials 205. For example, the word line contact pillars 270 may be formed by depositing a conductive material into the cavities 210 associated with the remaining sacrificial pillars 215 removed at processing step 200-s. Each word line contact pillar 270 may be coupled with a respective layer of the conductive material 260 via one or more respective lateral word line contacts 261. For example, the word line contact pillar 270-a may be coupled with the conductive material 260 at the target layer 208-a of the stack of materials 205 via the at least two lateral word line contacts 261. For example, the conductive material 260 may extend horizontally to form the one or more lateral word line contacts 261, which may extend into or at least be in direct contact with the word line contact pillar 270-a at the target layer 208-a. The conductive material 260 may extend horizontally to couple to the word line contact pillar 270-a at the target layer 208-a and not at other layers of the stack of materials 205 based on the processing steps described herein. For example, because the tiers 236 may be associated with (e.g., at a same level as) the target layer 208-a, the tier 236 may be used to access the target layer 208-a and remove and deposit one or more materials to form the lateral word line contacts 261 at the target layer 208-a as described herein. Likewise, another word line contact pillar 270 may be coupled with the conductive material 260 at the target layer 208-b of the stack of materials 205 via another respective lateral word line contact. Each word line contact pillar 270 may thereby form a conductive contact (e.g., a lateral word line contact) with a word line at a layer of the memory architecture. For example, the word line contact pillar 270-a may be coupled with the word line associated with the conductive material 260 at the target layer 208-a. In some cases, each word line contact pillar 270-a may be coupled with supporting circuitry beneath the memory architecture, which may be associated with activating the memory cells of the memory architecture.

The conductive material 260, which may be coupled with the memory cells in each layer via the memory cell pillars described herein, may thereby correspond to multiple word lines, with each word line being associated with a respective layer of the stack of materials 205. By activating a corresponding word line contact pillar 270, the memory system may active the word line that is coupled with the word line contact pillar 270 and may thereby access one or more memory cells coupled with the word line at the corresponding layer. The described techniques may thereby provide for an improved process for forming word line contacts via lateral etching within a memory system, which may improve efficiency and accuracy while reducing a size and overall footprint of the memory system, among other advantages. Although a single lateral word line contact per word line contact pillar 270 is described herein, it is to be understood that, in some examples, the described techniques may be used to for lateral contacts between a word line contact pillar 270 and two or more word lines at two or more target layers.

FIG. 3 shows an example of a memory architecture 300 that supports lateral word line contacts for memory devices in accordance with examples as disclosed herein. The memory architecture 300 may be implemented within a memory device, which may be an example of a memory device 100, as described with reference to FIG. 1. The memory architecture 300 may be resultant from a manufacturing process including processing steps, which may be examples of processing steps 200, as described with reference to FIGS. 2A through 2T. For illustrative purposes, aspects of the memory architecture 300 may be described with reference to an x-direction, a y-direction, and a z-direction of the illustrated coordinate systems. For example, FIG. 3 illustrates the memory architecture 300 from a top view in an xy-plane, where the memory architecture 300 extend a distance along the z-direction into the page (e.g., towards a substrate). The memory architecture 300 may include a quantity of pillars, where each pillar may be associated with a type of pillar, and each type of pillar may be associated with a different function. Each pillar may extend through a stack of materials to a substrate (e.g., not shown) of the memory architecture 300 along the z-direction.

The memory architecture 300 may include one or more array regions 305, which may include a quantity of cell pillars 310. The cell pillars 310 may be examples of cell pillars 220, as described with reference to FIG. 2D. The cell pillars 310 may each be associated with a quantity of memory cells. In some cases, the cell pillars 310 may be arranged in a grid-like pattern within the one or more array regions 305. For example, the cell pillars 310 may include one or more memory cells at layers of the memory architecture 300. The memory cells may be coupled with one or more word lines (e.g., not pictured in FIG. 3), which may correspond to the conductive material 260 described with reference to FIG. 2T. One or more memory cells at each layer of the device may be accessed via a respective word line.

The memory architecture 300 may include one or more contact regions 315, which may include a quantity of guard pillars 320 and a quantity of word line contact pillars 325. The guard pillars 320 may be examples of guard pillars 230 and the word line contact pillars 325 may be examples of word line contact pillars 270, as described with reference to FIGS. 2H and 2T, respectively. The word line contact pillars 325 may extend through the stack of materials in the z-direction and may form lateral word line contacts with word lines of the memory architecture 300. For example, each word line contact pillar 325 may be laterally coupled with a word line at a target layer of the memory architecture 300. Each word line contact pillar 325 may be associated with coupling supporting circuitry (e.g., string drivers, word line decoders, or other circuitry below the array) with word lines to support accessing memory cells of the memory architecture. For example, a memory cell at a layer of the memory architecture 300 may be accessed based on selecting the cell pillar 310 and activating the corresponding word line via the word line contact pillar 325 coupled with the word line at the layer of the memory architecture 300. The guard pillars 320 may be associated with preventing the word line contact pillars 325 from coupling to word lines at other layers not associated with the respective target layers. For example, each word line contact pillar 325 may couple with a respective word line at a respective target layer, and each word line contact pillar 325 may be surrounded by a subset of the guard pillars 320 and corresponding polysilicon material at other layers different than the target layer. The subset of the guard pillars 320 and corresponding polysilicon material may isolate the respective word line contact pillar 325 from contacting other word lines at other layers besides the word line at the respective target layer.

In some cases, each subset of the guard pillars 320 may at least partially surround the respective word line contact pillar 325 by forming a hexagonal shape with the word line contact pillar 325 in or near the center (e.g., toward a center, in a central region) of the hexagonal shape. In some cases, each subset of the guard pillars 320 may at least partially surround the respective word line contact pillar 325 by forming a pentagonal shape with the word line contact pillar 325 in or near the center or central region of the pentagonal shape. In some examples, the hexagonal shape or the pentagonal shape may be asymmetrical along one or more axis. Additionally, or alternatively, each subset of guard pillars 320 may be formed in any other shape, including a triangle, square, or some other shape that protects the word line contact pillars 325 from coupling with word lines at unintended layers. In some examples, each subset of guard pillars 320 may include a line of guard pillars 320 extending from the shape (e.g., similar to a keyhole shape). Such a shape may provide for the exhume of the polysilicon liner to be stopped once the cavity reaches the portion of the extension, which may reduce a distance of cavity etching and a pitch of the contact structure, among other examples.

The memory architecture 300 may include one or more staircase regions 330, which may include a quantity of cascading tiers 331. The staircase regions 330 may be examples of a staircase region 235, as described with reference to FIG. 2I. For example, each staircase region 330 may include tiers 331 which extend along the y-direction and cascade vertically along the z-direction, such that each tier 331 is associated with a different respective layer of the memory architecture 300. In some cases, the staircase region 330 may be used to form the lateral word line contacts between the word lines and the word line contact pillars 325, as described in further detail elsewhere herein, including with reference to FIGS. 2A through 2T. The memory architecture 300 may include a quantity of electrically isolating pillars 335 surrounding each staircase region 330. The electrically isolating pillars 335 may be examples of electrically isolating pillars 265, as described with reference to FIG. 2R. The electrically isolating pillars 335 may include dielectric material associated with electrically isolating the respective staircase region 330 from the contact regions 315 and/or the array regions 305. In some cases, the memory architecture 300 may include support pillars 340 surrounding each staircase region 330. For example, the support pillars may provide mechanical (e.g., structural support) for the memory architecture 300.

In some cases, the one or more array regions 305 may be positioned next to the one or more contact regions 315 along the y-direction. In some cases, each contact region 315 may be positioned between respective staircase regions 330 along the x-direction. Each contact region 315 may include subsets of the guard pillars 320 positioned in one or more patterns. In some examples, the subsets of guard pillars 320 may be positioned in an alternating (e.g., zig-zag) pattern along an axis that extends, in the y-direction, down a central portion of the contact region. For example, as illustrated in FIG. 3, each subset of the guard pillars 320 may be staggered in the x and y-directions (e.g., offset from a y-axis in the x-direction). That is, each contact region 315 may include two or more columns of subsets of the guard pillars 320, where a central axis (e.g., in the y-direction) of each column may be offset in the x-direction from a central axis (e.g., in the y-direction) of an adjacent column. In some examples, although the central axis may be offset in the x-direction, at least a portion of the subsets of guard pillars 320 in each column may overlap in the x-direction, as illustrated in FIG. 3. If a contact region 315 includes two or more columns of subsets of guard pillars 320, each contact region 315 may be associated with two or more staircase regions 330. For example, a first column of subsets of guard pillars 320 in a contact region 315 may be associated with tiers 331 within a first staircase region 330, and a second column of subsets of guard pillars 320 in the same contact region 315 may be associated with tiers 331 within a second staircase region 330. The association between a tier 331 and a subset of guard pillars 320 may indicate that the tier 331 may be at a level (e.g., in the z-direction) at which a word line may be coupled with the word line contact pillar 325 that is at least partially surrounded by the subset of guard pillars 320. For example, the tier 331 may be used to access and form a connection between a word line and the word line contact pillar 325 at the level, as described in further detail elsewhere herein, including with reference to FIGS. 2A-2T.

In other examples (not pictured in FIG. 3), each contact region 315 may include a singular column of subsets of guard pillars 320 that are mostly aligned in the y-direction. In some such examples, the subsets of the guard pillars 320 may form asymmetrical pentagons (e.g., or another shape) that alternate along the y-direction of the singular column, such that each asymmetrical pentagon may be mirrored about an axis in the y-direction compared to adjacent subsets of the guard pillars 320 within the column. Additionally, or alternatively, the subsets of the guard pillars 320 may each be hexagonal or any other symmetrical shape, and may be aligned along the y-axis within a singular column. In some examples, if there is a singular column of subsets of guard pillars 320 in each contact region 315, each contact region 315 may be associated with a single staircase region 330. That is, the staircase region 330 may support a contact region 315 on each side of the staircase region 330 in the x-direction, and those contact regions 315 may not support or be associated with any other staircase regions 330.

In some cases, the electrically isolating pillars 335 may be positioned at least partially surrounding each staircase region 330 along the x-direction and at least a portion of the y-direction. The electrically isolating pillars 335 may form a y-shape around the staircase region 330, for example, where a tail of the y-shape may extend through the one or more array regions 305. In some cases, the memory architecture 300 may include a singular staircase region 330, and contact regions 315 adjacent to the staircase region 330 relative to the x-direction. In some such cases, the electrically isolating pillars 335 may form a y-shape around the singular staircase region 330, and may include a column of electrically isolating pillars 335 adjacent to the contact regions 315 on either side of the contact regions 315 relative to the x-direction. In some examples, the support pillars 340 may be positioned between the electrically isolating pillars 335 and the staircase region 330 along the x-direction and the y-direction. In some cases, the guard pillars 320 may be positioned between the staircase region 330 and the word line contact pillar 325.

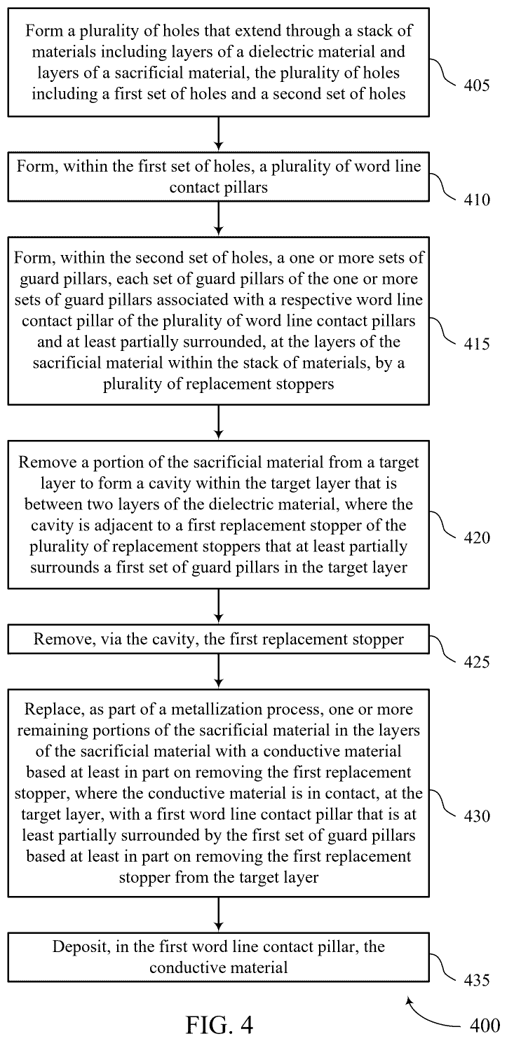

FIG. 4 shows a flowchart illustrating a method 400 that supports lateral word line contacts for memory devices in accordance with examples as disclosed herein. The operations of method 400 may be implemented by a manufacturing system or its components as described herein. For example, the operations of method 400 may be performed by a manufacturing system as described with reference to FIGs.. In some examples, a manufacturing system may execute a set of instructions to control the functional elements of the device to perform the described functions. Additionally, or alternatively, the manufacturing system may perform aspects of the described functions using special-purpose hardware.

At 405, the method may include forming a plurality of holes that extend through a stack of materials including layers of a dielectric material and layers of a sacrificial material, the plurality of holes including a first set of holes and a second set of holes.

At 410, the method may include forming, within the first set of holes, a plurality of word line contact pillars.

At 415, the method may include forming, within the second set of holes, a one or more sets of guard pillars, each set of guard pillars of the one or more sets of guard pillars associated with a respective word line contact pillar of the plurality of word line contact pillars and at least partially surrounded, at the layers of the sacrificial material within the stack of materials, by a plurality of replacement stoppers.

At 420, the method may include removing a portion of the sacrificial material from a target layer to form a cavity within the target layer that is between two layers of the dielectric material, where the cavity is adjacent to a first replacement stopper of the plurality of replacement stoppers that at least partially surrounds a first set of guard pillars in the target layer.

At 425, the method may include removing, via the cavity, the first replacement stopper.

At 430, the method may include replacing, as part of a metallization process, one or more remaining portions of the sacrificial material in the layers of the sacrificial material with a conductive material based at least in part on removing the first replacement stopper, where the conductive material is in contact, at the target layer, with a first word line contact pillar that is at least partially surrounded by the first set of guard pillars based at least in part on removing the first replacement stopper from the target layer.

At 435, the method may include depositing, in the first word line contact pillar, the conductive material.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a plurality of holes that extend through a stack of materials including layers of a dielectric material and layers of a sacrificial material, the plurality of holes including a first set of holes and a second set of holes; forming, within the first set of holes, a plurality of word line contact pillars; forming, within the second set of holes, one or more sets of guard pillars, each set of guard pillars of the one or more sets of guard pillars associated with a respective word line contact pillar of the plurality of word line contact pillars and at least partially surrounded, at the layers of the sacrificial material within the stack of materials, by a plurality of replacement stoppers; removing a portion of the sacrificial material from a target layer to form a cavity within the target layer that is between two layers of the dielectric material, where the cavity is adjacent to a first replacement stopper of the plurality of replacement stoppers that at least partially surrounds a first set of guard pillars in the target layer; removing, via the cavity, the first replacement stopper; replacing, as part of a metallization process, one or more remaining portions of the sacrificial material in the layers of the sacrificial material with a conductive material based at least in part on removing the first replacement stopper, where the conductive material is in contact, at the target layer, with a first word line contact pillar that is at least partially surrounded by the first set of guard pillars based at least in part on removing the first replacement stopper from the target layer; and depositing, in the first word line contact pillar, the conductive material.

Aspect 2: The method, apparatus, or non-transitory computer-readable medium of aspect 1, further including operations, features, circuitry, logic, means, or instructions, or any combination thereof for etching, within a staircase region of the memory device, the layers of the dielectric material and the layers of the sacrificial material in the stack of materials to form a plurality of cascading tiers, where each tier of the plurality of cascading tiers is associated with a different set of guard pillars of the one or more sets of guard pillars and includes the dielectric material and the sacrificial material, and where the portion of the sacrificial material is removed via a first tier of the plurality of cascading tiers within the staircase region, and where the first tier is associated with the first set of guard pillars.

Aspect 3: The method, apparatus, or non-transitory computer-readable medium of aspect 2, further including operations, features, circuitry, logic, means, or instructions, or any combination thereof for depositing a staircase liner in the staircase region based at least in part on etching the layers of the dielectric material and the layers of the sacrificial material within the staircase region, where the staircase liner forms on sidewalls of the stack of materials within the staircase region, the staircase liner associated with protection of portions of the sacrificial material surrounding the staircase region and where removing the portion of the sacrificial material via the first tier in the staircase region is based at least in part on forming the staircase liner.

Aspect 4: The method, apparatus, or non-transitory computer-readable medium of aspect 3, where the staircase liner includes a polysilicon material.

Aspect 5: The method, apparatus, or non-transitory computer-readable medium of any of aspects 2 through 3, further including operations, features, circuitry, logic, means, or instructions, or any combination thereof for depositing, based at least in part on removing the first replacement stopper, a structural material in the staircase region, where the structural material fills a portion of the stack of materials that was removed based at least in part on etching within the staircase region, where the structural material fills the plurality of cascading tiers, and where replacing the one or more remaining portions of the sacrificial material in the layers of the sacrificial material with the conductive material is based at least in part on depositing the structural material.

Aspect 6: The method, apparatus, or non-transitory computer-readable medium of any of aspects 1 through 5, further including operations, features, circuitry, logic, means, or instructions, or any combination thereof for depositing, in a third set of holes of the plurality of holes, a memory material to form a plurality of memory cell pillars that extend through the stack of materials, where the plurality of memory cell pillars include a plurality of memory cells within the layers of the sacrificial material and depositing, above the memory material in the third set of holes, a polysilicon material to form a plurality of polysilicon plugs above the plurality of memory cells in the plurality of memory cell pillars.

Aspect 7: The method, apparatus, or non-transitory computer-readable medium of any of aspects 1 through 6, where forming the plurality of holes includes operations, features, circuitry, logic, means, or instructions, or any combination thereof for removing, via a high aspect ratio contact etch procedure, material from the stack of materials to form the plurality of holes that extend through the stack of materials.

Aspect 8: The method, apparatus, or non-transitory computer-readable medium of any of aspects 1 through 7, where forming the one or more sets of guard pillars includes operations, features, circuitry, logic, means, or instructions, or any combination thereof for depositing a second sacrificial material in the plurality of holes based at least in part on forming the plurality of holes; removing the second sacrificial material from the second set of holes; removing portions of the sacrificial material that at least partially surround the second set of holes within the layers of the stack of materials based at least in part on removing the second sacrificial material from the second set of holes, where removal of the sacrificial material forms a plurality of recesses that surround the second set of holes at the layers of the stack of materials; depositing and recessing a replacement stopper material to form the plurality of replacement stoppers within the plurality of recesses; and depositing a second dielectric material in the second set of holes based at least in part on depositing the replacement stopper material to form the one or more sets of guard pillars.

Aspect 9: The method, apparatus, or non-transitory computer-readable medium of any of aspects 1 through 8, further including operations, features, circuitry, logic, means, or instructions, or any combination thereof for replacing the first replacement stopper with the sacrificial material and where replacing the one or more remaining portions of the sacrificial material in the layers of the sacrificial material with the conductive material is based at least in part on replacing the first replacement stopper with the sacrificial material.

Aspect 10: The method, apparatus, or non-transitory computer-readable medium of any of aspects 1 through 9, further including operations, features, circuitry, logic, means, or instructions, or any combination thereof for depositing, within a fourth set of holes of the plurality of holes that extend through the stack of materials, a barrier material to form a plurality of electrically isolating pillars that at least partially surround a staircase region of the memory device.

Aspect 11: The method, apparatus, or non-transitory computer-readable medium of any of aspects 1 through 10, where one or more second remaining portions of the sacrificial material that are positioned between the one or more sets of guard pillars and the plurality of word line contact pillars remain after replacing the one or more remaining portions of the sacrificial material with the conductive material as part of the metallization process based at least in part on the one or more second remaining portions of the sacrificial material being at least partially surrounded by the plurality of replacement stoppers.

Aspect 12: The method, apparatus, or non-transitory computer-readable medium of any of aspects 1 through 11, where forming the plurality of word line contact pillars includes operations, features, circuitry, logic, means, or instructions, or any combination thereof for depositing a second sacrificial material in the first set of holes based at least in part on forming the plurality of holes.

Aspect 13: The method, apparatus, or non-transitory computer-readable medium of aspect 12, further including operations, features, circuitry, logic, means, or instructions, or any combination thereof for removing the second sacrificial material from the first set of holes of the plurality of holes based at least in part on replacing the one or more remaining portions of the sacrificial material in the layers of the sacrificial material with the conductive material and depositing, based at least in part on removing the second sacrificial material from the first set of holes, the conductive material within the first set of holes to form a plurality of conductive word line contact pillars.

Aspect 14: The method, apparatus, or non-transitory computer-readable medium of any of aspects 1 through 13, further including operations, features, circuitry, logic, means, or instructions, or any combination thereof for forming the plurality of replacement stoppers based on depositing and recessing a polysilicon material.

Aspect 15: The method, apparatus, or non-transitory computer-readable medium of any of aspects 1 through 13, where the dielectric material includes an oxide material and the sacrificial material includes a nitride material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 16: A memory device, including: a stack of materials including layers of a conductive material and layers of a dielectric material, each layer of conductive material of the layers of the conductive material including one or more word lines; a plurality of cell pillars that extend through the stack of materials, each cell pillar of the plurality of cell pillars including a plurality of memory cells, where the one or more word lines are coupled with the plurality of cell pillars within the layers of the conductive material; a plurality of word line contact pillars that extend through the stack of materials, each word line contact pillar of the plurality of word line contact pillars coupled with a respective word line of the one or more word lines at a respective target layer of the stack of materials; and one or more sets of guard pillars, each set of guard pillars of the one or more sets of guard pillars associated with isolation of a respective word line contact pillar from a subset of the one or more word lines at layers of the stack of materials that are different than the respective target layer, where each set of guard pillars of the one or more sets of guard pillars is at least partially surrounded by a respective liner material at the layers of the stack of materials that are different than the respective target layer.

Aspect 17: The memory device of aspect 16, further including: a plurality of array regions including the plurality of cell pillars; a plurality of contact regions including the plurality of word line contact pillars and the one or more sets of guard pillars; a staircase region positioned between two contact regions of the plurality of contact regions; and a plurality of electrically isolating pillars that extend through the stack of materials and at least partially surround the staircase region, where a subset of the plurality of electrically isolating pillars extend between two array regions of the plurality of array regions.

Aspect 18: The memory device of aspect 17, where the staircase region includes: a staircase formation of cascading tiers of material within the stack of materials, where each tier of the cascading tiers is associated with a different set of guard pillars of the one or more sets of guard pillars and includes at least the dielectric material. In some cases, the staircase region may not include pillars.

Aspect 19: The memory device of aspect 18, where the staircase formation is electrically isolated from the plurality of array regions and the plurality of contact regions.

Aspect 20: The memory device of any of aspects 17 through 18, where the one or more sets of guard pillars include: one or more first sets of guard pillars that extend along a first side of the staircase region, where a first subset of electrically isolating pillars of the plurality of electrically isolating pillars is positioned between the one or more first sets of guard pillars and the staircase region; and one or more second sets of guard pillars that extend along a second side of the staircase region, where a second subset of electrically isolating pillars of the plurality of electrically isolating pillars is positioned between the one or more second sets of guard pillars and the staircase region.

Aspect 21: The memory device of any of aspects 17 through 20, where the one or more sets of guard pillars include: one or more first sets of guard pillars that extend along a first axis adjacent to a first side of the staircase region, where a first subset of electrically isolating pillars of the plurality of electrically isolating pillars is positioned between the one or more first sets of guard pillars and the first side of the staircase region; one or more second sets of guard pillars that extend along a second axis adjacent to a second side of the staircase region that is opposite to the first side of the staircase region, where a second subset of electrically isolating pillars of the plurality of electrically isolating pillars is positioned between the one or more second sets of guard pillars and the second side of the staircase region; and one or more third sets of guard pillars that extend along a third axis parallel to the first axis and adjacent to a third side of a second staircase region, where the one or more first sets of guard pillars and the one or more third sets of guard pillars are positioned between the staircase region and the second staircase region, and where a third subset of electrically isolating pillars of a second plurality of electrically isolating pillars is positioned between the one or more third sets of guard pillars and the third side of the second staircase region.

Aspect 22: The memory device of any of aspects 16 through 21, where each set of guard pillars of the one or more sets of guard pillars is arranged in a hexagonal pattern at least partially surrounding the respective word line contact pillar.

Aspect 23: The memory device of any of aspects 16 through 22, where each set of guard pillars of the one or more sets of guard pillars is arranged in a pentagonal pattern at least partially surrounding the respective word line contact pillar.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a stack of materials comprising layers of a conductive material and layers of a dielectric material, each layer of the conductive material of the layers of the conductive material comprising one or more word lines;
a plurality of cell pillars that extend through the stack of materials, each cell pillar of the plurality of cell pillars comprising a plurality of memory cells, wherein the one or more word lines are coupled with the plurality of cell pillars within the layers of the conductive material;
a plurality of word line contact pillars that extend through the stack of materials, each word line contact pillar of the plurality of word line contact pillars coupled with a respective word line of the one or more word lines at a respective target layer of the stack of materials; and
one or more sets of guard pillars, each set of guard pillars of the one or more sets of guard pillars associated with isolation of a respective word line contact pillar from a subset of the one or more word lines at layers of the stack of materials that are different than the respective target layer, wherein each set of guard pillars of the one or more sets of guard pillars is at least partially surrounded by a respective liner material at the layers of the stack of materials that are different than the respective target layer.

2. The memory device of claim 1, further comprising:
a plurality of array regions comprising the plurality of cell pillars;
a plurality of contact regions comprising the plurality of word line contact pillars and the one or more sets of guard pillars;
a staircase region positioned between two contact regions of the plurality of contact regions; and
a plurality of electrically isolating pillars that extend through the stack of materials and at least partially surround the staircase region, wherein a subset of the plurality of electrically isolating pillars extend between two array regions of the plurality of array regions.

3. The memory device of claim 2, wherein the staircase region comprises:
a staircase formation of cascading tiers of material within the stack of materials, wherein each tier of the cascading tiers is associated with a different set of guard pillars of the one or more sets of guard pillars and comprises at least the dielectric material.

4. The memory device of claim 3, wherein the staircase formation is electrically isolated from the plurality of array regions and the plurality of contact regions.

5. The memory device of claim 2, wherein the one or more sets of guard pillars comprise:
one or more first sets of guard pillars that extend along a first side of the staircase region, wherein a first subset of electrically isolating pillars of the plurality of electrically isolating pillars is positioned between the one or more first sets of guard pillars and the staircase region; and
one or more second sets of guard pillars that extend along a second side of the staircase region, wherein a second subset of electrically isolating pillars of the plurality of electrically isolating pillars is positioned between the one or more second sets of guard pillars and the staircase region.

6. The memory device of claim 2, wherein the one or more sets of guard pillars comprise:
one or more first sets of guard pillars that extend along a first axis adjacent to a first side of the staircase region, wherein a first subset of electrically isolating pillars of the plurality of electrically isolating pillars is positioned between the one or more first sets of guard pillars and the first side of the staircase region;
one or more second sets of guard pillars that extend along a second axis adjacent to a second side of the staircase region that is opposite to the first side of the staircase region, wherein a second subset of electrically isolating pillars of the plurality of electrically isolating pillars is positioned between the one or more second sets of guard pillars and the second side of the staircase region; and
one or more third sets of guard pillars that extend along a third axis parallel to the first axis and adjacent to a third side of a second staircase region, wherein the one or more first sets of guard pillars and the one or more third sets of guard pillars are positioned between the staircase region and the second staircase region, and wherein a third subset of electrically isolating pillars of a second plurality of electrically isolating pillars is positioned between the one or more third sets of guard pillars and the third side of the second staircase region.

7. The memory device of claim 1, wherein each set of guard pillars of the one or more sets of guard pillars is arranged in a hexagonal pattern at least partially surrounding the respective word line contact pillar.

8. The memory device of claim 1, wherein each set of guard pillars of the one or more sets of guard pillars is arranged in a pentagonal pattern at least partially surrounding the respective word line contact pillar.

9. A method of manufacturing a memory device, comprising:
forming a plurality of holes that extend through a stack of materials comprising layers of a dielectric material and layers of a sacrificial material, the plurality of holes comprising a first set of holes and a second set of holes;
forming, within the first set of holes, a plurality of word line contact pillars;
forming, within the second set of holes, one or more sets of guard pillars, each set of guard pillars of the one or more sets of guard pillars associated with a respective word line contact pillar of the plurality of word line contact pillars and at least partially surrounded, at the layers of the sacrificial material within the stack of materials, by a plurality of replacement stoppers;
removing a portion of the sacrificial material from a target layer to form a cavity within the target layer that is between two layers of the dielectric material, wherein the cavity is adjacent to a first replacement stopper of the plurality of replacement stoppers that at least partially surrounds a first set of guard pillars in the target layer;
removing, via the cavity, the first replacement stopper;
replacing, as part of a metallization process, one or more remaining portions of the sacrificial material in the layers of the sacrificial material with a conductive material based at least in part on removing the first replacement stopper, wherein the conductive material is in contact, at the target layer, with a first word line contact pillar that is at least partially surrounded by the first set of guard pillars based at least in part on removing the first replacement stopper from the target layer; and
depositing, in the first word line contact pillar, the conductive material.

10. The method of claim 9, further comprising:
etching, within a staircase region of the memory device, the layers of the dielectric material and the layers of the sacrificial material in the stack of materials to form a plurality of cascading tiers, wherein each tier of the plurality of cascading tiers is associated with a different set of guard pillars of the one or more sets of guard pillars and comprises the dielectric material and the sacrificial material, and wherein the portion of the sacrificial material is removed via a first tier of the plurality of cascading tiers within the staircase region, and wherein the first tier is associated with the first set of guard pillars.

11. The method of claim 10, further comprising:
depositing a staircase liner in the staircase region based at least in part on etching the layers of the dielectric material and the layers of the sacrificial material within the staircase region, wherein the staircase liner forms on sidewalls of the stack of materials within the staircase region, the staircase liner associated with protection of portions of the sacrificial material surrounding the staircase region,
wherein removing the portion of the sacrificial material via the first tier in the staircase region is based at least in part on forming the staircase liner.

12. The method of claim 11, wherein the staircase liner comprises a polysilicon material.

13. The method of claim 10, further comprising:
depositing, based at least in part on removing the first replacement stopper, a structural material in the staircase region, wherein the structural material fills a portion of the stack of materials that was removed based at least in part on etching within the staircase region, wherein the structural material fills the plurality of cascading tiers, and wherein replacing the one or more remaining portions of the sacrificial material in the layers of the sacrificial material with the conductive material is based at least in part on depositing the structural material.

14. The method of claim 9, further comprising:
depositing, in a third set of holes of the plurality of holes, a memory material to form a plurality of memory cell pillars that extend through the stack of materials, wherein the plurality of memory cell pillars comprise a plurality of memory cells within the layers of the sacrificial material; and
depositing, above the memory material in the third set of holes, a replacement stopper material to form a plurality of polysilicon plugs above the plurality of memory cells in the plurality of memory cell pillars.

15. The method of claim 9, wherein forming the plurality of holes comprises:
removing, via a high aspect ratio contact etch procedure, material from the stack of materials to form the plurality of holes that extend through the stack of materials.

16. The method of claim 9, wherein forming the one or more sets of guard pillars comprises:
depositing a second sacrificial material in the plurality of holes based at least in part on forming the plurality of holes;
removing the second sacrificial material from the second set of holes;
removing portions of the sacrificial material that at least partially surround the second set of holes within the layers of the stack of materials based at least in part on removing the second sacrificial material from the second set of holes, wherein removal of the sacrificial material forms a plurality of recesses that surround the second set of holes at the layers of the stack of materials;
depositing and recessing a replacement stopper material to form the plurality of replacement stoppers within the plurality of recesses; and
depositing a second dielectric material in the second set of holes based at least in part on depositing the replacement stopper material to form the one or more sets of guard pillars.

17. The method of claim 9, further comprising:
replacing the first replacement stopper with the sacrificial material,
wherein replacing the one or more remaining portions of the sacrificial material in the layers of the sacrificial material with the conductive material is based at least in part on replacing the first replacement stopper with the sacrificial material.

18. The method of claim 9, further comprising:
depositing, within a fourth set of holes of the plurality of holes that extend through the stack of materials, a barrier material to form a plurality of electrically isolating pillars that at least partially surround a staircase region of the memory device.

19. The method of claim 9, wherein one or more second remaining portions of the sacrificial material that are positioned between the one or more sets of guard pillars and the plurality of word line contact pillars remain after replacing the one or more remaining portions of the sacrificial material with the conductive material as part of the metallization process based at least in part on the one or more second remaining portions of the sacrificial material being at least partially surrounded by the plurality of replacement stoppers.

20. The method of claim 9, wherein forming the plurality of word line contact pillars comprises:
depositing a second sacrificial material in the first set of holes based at least in part on forming the plurality of holes.

21. The method of claim 20, wherein further comprising:
removing the second sacrificial material from the first set of holes of the plurality of holes based at least in part on replacing the one or more remaining portions of the sacrificial material in the layers of the sacrificial material with the conductive material; and
depositing, based at least in part on removing the second sacrificial material from the first set of holes, the conductive material within the first set of holes to form a plurality of conductive word line contact pillars.

22. The method of claim 9, further comprising:
forming the plurality of replacement stoppers based at least in part on depositing and recessing a polysilicon material.

23. The method of claim 9, wherein the dielectric material comprises an oxide material and the sacrificial material comprises a nitride material.
